(19) United States
(12) Patent Application Publication
(10) Pub. No.: US 2017/0221988 A1
(43) Pub. Date: Aug. 3, 2017

(54) Method of Manufacturing Semiconductor Devices Including Deposition of Crystalline Silicon in Trenches

(71) Applicant: Infineon Technologies Austria AG, Villach (AT)

(72) Inventors: Johannes Baumgartl, Riegersdorf (AT); Matthias Kuenle, Villach (AT)

(21) Appl. No.: 15/417,939

(22) Filed: Jan. 27, 2017

(30) Foreign Application Priority Data
Jan. 28, 2016 (DE) 102016101559.8

(51) Int. Cl. H01L 29/06; H01L 21/02; H01L 21/3065

(52) U.S. Cl. CPC H01L 29/0634; H01L 21/3065; H01L 21/02532; H01L 21/0257; H01L 21/02647

(57) ABSTRACT

Trenches are formed in a semiconductor layer of a semiconductor substrate. A mixture that contains trichlorosilane and hydrogen gas is fed into a process chamber containing the semiconductor substrate. A barometric pressure in the process chamber is at least 50% of standard atmosphere. The trenches are filled with epitaxially deposited crystalline silicon.

### BACKGROUND

In superjunction devices oppositely doped regions formed in a drift layer effectively cancel out their mobile charge. The resulting depletion region facilitates high blocking voltages even at comparatively high dopant concentrations in the doped regions, wherein the high doping level of the doped regions ensures low on-state resistance. Typically, the manufacture of superjunction devices includes growing n-doped epitaxy layers and implanting acceptor atoms in each epitaxy layer before forming the next n-doped epitaxy layer. Another approach includes etching trenches in an n-doped epitaxial layer and filling the trenches with p-doped semiconductor material. Shrinking a lateral dimension of the doped regions of the superjunction structure allows for increasing the dopant concentration in the doped regions and results in better on-state resistance.

It is desirable to provide superjunction semiconductor devices with narrow lateral dimensions of the doped regions of the superjunction structure.

### SUMMARY

According to an embodiment a method of manufacturing a semiconductor device includes forming trenches in a semiconductor layer of a semiconductor substrate. Into a process chamber that contains the semiconductor substrate a mixture is fed that contains trichlorosilane and hydrogen gas. A barometric pressure in the process chamber is at least 50% of standard atmosphere. The trenches are filled with epitaxially deposited crystalline silicon.

According to another embodiment a superjunction semiconductor device includes a semiconductor portion including a drift layer. The drift layer includes n-doped first regions and p-doped second regions. The first and second regions alternate along at least one horizontal direction parallel to a first surface of the semiconductor portion. An aspect ratio of a vertical extension of the second regions to a horizontal width of the second regions is at least 20.

Those skilled in the art will recognize additional features and advantages upon reading the following detailed description and on viewing the accompanying drawings.

### BRIEF DESCRIPTION OF THE DRAWINGS

The accompanying drawings are included to provide a further understanding of the invention and are incorporated in and constitute a part of this specification. The drawings illustrate the embodiments of the present invention and together with the description serve to explain principles of the invention. Other embodiments of the invention and intended advantages will be readily appreciated as they become better understood by reference to the following detailed description.

FIG. 1 is a simplified flowchart for illustrating a method of manufacturing a superjunction semiconductor device, wherein an epitaxy process fills trenches by using trichlorosilane and hydrogen gas as process gases according to an embodiment.

FIG. 2A is a schematic vertical cross-sectional view of a portion of a semiconductor substrate for illustrating a method of manufacturing semiconductor devices by epitaxial fill of trenches according to an embodiment including epitaxial growth on semiconducting sidewalls, after forming trenches.

FIG. 2B is a schematic vertical cross-sectional view of the semiconductor substrate portion of FIG. 2A, after filling the trenches by epitaxy.

FIG. 3A is a schematic vertical cross-sectional view of a portion of a semiconductor substrate for illustrating a method of manufacturing semiconductor devices by epitaxial fill of trenches according to an embodiment including epitaxial growth in trenches with sidewalls covered by a passivation liner.

FIG. 3B is a schematic vertical cross-sectional view of the semiconductor substrate portion of FIG. 3A, after filling the trenches by epitaxy.

FIG. 4 is a schematic cross-sectional view of a process reactor for epitaxial growth according to a further embodiment.

FIG. 5A is a schematic vertical cross-sectional view of a portion of a semiconductor substrate for illustrating a method of manufacturing semiconductor devices according to an embodiment, after forming a trench etch mask.

FIG. 5B is a vertical cross-sectional view of the semiconductor substrate portion of FIG. 5A, after forming trenches.

FIG. 5C is a schematic vertical cross-sectional view of the semiconductor substrate portion of FIG. 5B, after filling the trenches by epitaxy.

FIG. 5D is a schematic vertical cross-sectional view of the semiconductor substrate portion of FIG. 5C, after planarization of deposited crystalline silicon.

FIG. 5E is a schematic vertical cross-sectional view of the semiconductor substrate portion of FIG. 5D, after forming gate structures.

FIG. 6A is a schematic vertical cross-sectional view of a portion of a semiconductor substrate for illustrating a method of manufacturing a superjunction semiconductor device according to an embodiment with epitaxially deposited crystalline silicon containing donors deposited in first trenches and epitaxially deposited crystalline silicon containing acceptors deposited in second trenches, after forming the first trenches.

FIG. 6B is a schematic vertical cross-sectional view of the semiconductor substrate portion of FIG. 6A, after selectively forming first regions of a superjunction structure in the first trenches.

FIG. 6C is a schematic vertical cross-sectional view of the semiconductor substrate portion of FIG. 6B, after forming second regions of the superjunction structure in second trenches between the first trenches.

FIG. 7 is a schematic vertical cross-sectional view of a portion of a semiconductor device with a superjunction structure that includes oppositely doped regions with high aspect ratios according to an embodiment.

### DETAILED DESCRIPTION

In the following detailed description, reference is made to the accompanying drawings, which form a part hereof and in which are shown by way of illustrations specific embodiments in which the invention may be practiced. It is to be understood that other embodiments may be utilized and structural or logical changes may be made without departing from the scope of the present invention. For example, features illustrated or described for one embodiment can be used on or in conjunction with other embodiments to yield yet a further embodiment. It is intended that the present invention includes such modifications and variations. The examples are described using specific language, which should not be construed as limiting the scope of the appending claims. The drawings are not scaled and are for illustrative purposes only. Corresponding elements are designated by the same reference signs in the different drawings if not stated otherwise.

The terms “having”, “containing”, “including”, “comprising” and the like are open, and the terms indicate the presence of stated structures, elements or features but do not preclude additional elements or features. The articles “a”, “an” and “the” are intended to include the plural as well as the singular, unless the context clearly indicates otherwise.

The term “electrically connected” describes a permanent low-ohmic connection between electrically connected elements, for example a direct contact between the concerned elements or a low-ohmic connection through a metal and/or a highly doped semiconductor. The term “electrically coupled” includes that one or more intervening element(s) adapted for signal transmission may be provided between the electrically coupled elements, for example elements that are controllable to temporarily provide a low-ohmic connection in a first state and a high-ohmic electric decoupling in a second state.

The Figures illustrate relative doping concentrations by indicating “−” or “+” next to the doping type “n” or “p”. For example, “n−” means a doping concentration which is lower than the doping concentration of an “n”-doping region while an “n+”-doping region has a higher doping concentration than an “n”-doping region. Doping regions of the same relative doping concentration do not necessarily have the same absolute doping concentration. For example, two different “n”-doping regions may have the same or different absolute doping concentrations.

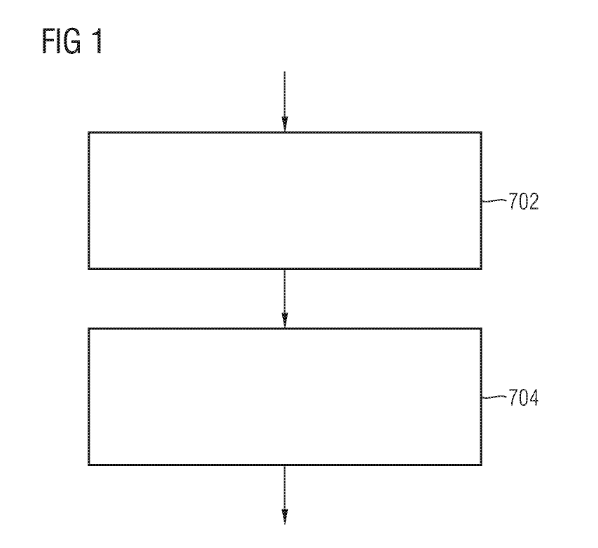

FIG. 1 illustrates a process flow for a superjunction semiconductor device with a superjunction structure including oppositely doped first and second regions resulting at least partly from the epitaxial fill of trenches temporarily formed in a semiconductor portion.

Trenches are formed in a semiconductor layer of a semiconductor substrate 702. The semiconductor layer is of single crystalline semiconductor material with a cubic crystal lattice, e.g. silicon (Si), germanium (Ge), a silicon germanium crystal (SiGe) or another A_{III}B_{V} semiconductor. The trenches may form a regular pattern, e.g., a pattern of regularly spaced parallel stripes, wherein a length of the stripes is at least ten times a width of the trenches. According to other embodiments the length of the trenches is less than ten times a width of the trenches, e.g., both lateral dimensions are approximately the same. For example, a horizontal cross-section of the trenches parallel to a first surface of the semiconductor substrate may be a polygon, e.g. a square, a hexagon or an octagon, with or without rounded or chamfered corners.

A center-to-center distance of the trenches may be in a range from 2 μm to 20 μm, for example in a range from 5 μm to 12 μm. A vertical extension of the trenches may be in a range from 10 μm to 100 μm, for example in a range from 20 μm to 60 μm. Sidewalls of the trenches may be approximately vertical or may taper with an angle of 1 degree or less with respect to a normal on a process surface of the semiconductor layer.

The semiconductor substrate is placed in a process chamber in which a barometric pressure is at least 50%, e.g., at least 90% or 100%, of standard atmosphere, wherein the barometric pressure of standard atmosphere is 1013.25 hPa, or ambient pressure. In the process chamber, the semiconductor substrate 500a is heated to a temperature of at least 800° C., for example, at least 920° C. or at least 980° C. A mixture containing trichlorosilane HSiCl₃ and hydrogen gas H₂ is fed into the process chamber 704 at a TCS:H₂ mass ratio in a range from 10:1 to 2:1, e.g., from 5:1 to 3:1.

At the process surface of the semiconductor substrate TCS or decomposition molecules of TCS and hydrogen react to silicon (Si) and hydrochloric acid (HCl), wherein the silicon atoms are fitted into the crystal lattice of the semiconductor layer 100a, wherein the depositing silicon atoms orient themselves to the crystal lattice of the crystalline semiconductor layer.

Using TCS as silicon source allows for performing the process at high temperatures of above 800° C. or above 920° C. such that high deposition rates can be achieved at high quality of the deposited crystal.

For example, a mixture containing TCS and hydrogen gas with a ratio of TCS to H₂ of 1 to 15 is fed into the process chamber at a TCS mass flow of 4 slm, at a temperature of the semiconductor substrate of at least 950° C., for example 975° C. and at a barometric pressure of about 980 hPa. A resulting deposition rate may be in a range from 50 nm/min to 500 nm/min, for example in a range from 300 nm/min to 450 nm/min.

Compared to methods using silicon tetrachloride (SiCl₄), DCS (dichlorosilane, SiH₂Cl₂), silane (SiH₄), disilane or other silicon-containing gases, the silicon crystal grown according to the embodiment is without shrinkage cavities and voids even at high deposition rates. By changing, in the course of deposition, the composition of the supplied process gas, for example, by temporarily feeding an etching agent such as hydrogen acid the epitaxy can be controlled to fill trenches with sidewalls lined by a passivation liner. Since TCS is available at high purity compared to other silicon sources, the deposited crystalline silicon contains less contaminant atoms. In addition wafer bowing is small.

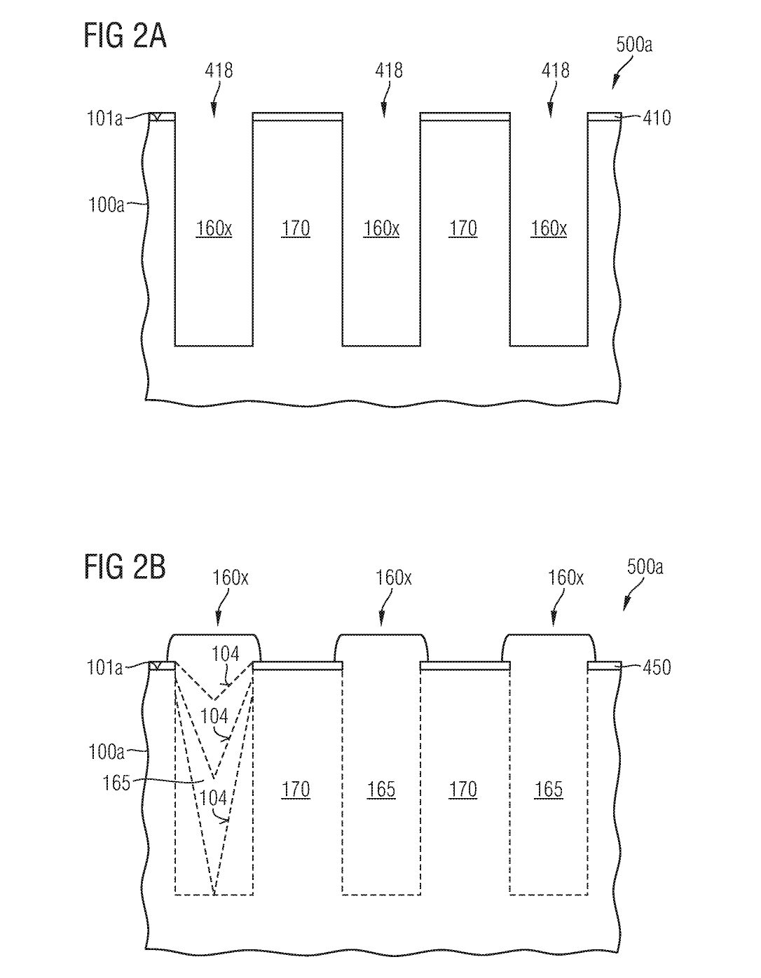

FIGS. 2A to 2B refer to the manufacture of a superjunction semiconductor device, wherein doped regions of the superjunction structure are formed by filling trenches with semiconducting sidewalls.

A trench etch mask layer is formed on a process surface 101a at a front side of a semiconductor substrate 500a that consists of or includes a semiconductor layer 100a of a crystalline semiconductor material. The semiconductor substrate 500a may be a semiconductor wafer from which a plurality of identical semiconductor dies is obtained. Apart from the semiconductor layer 100a, the semiconductor substrate 500a may include further semiconducting portions, for example, a heavily doped substrate portion directly adjoining to the semiconductor layer 100a on the back, or an insulator portion.

The semiconductor material of the semiconductor layer 100a may be Si, Ge, SiGe or any other A_{III}B_{V} semiconductor. The semiconductor layer 100a may be a layer grown by epitaxy on a single crystalline substrate portion. The semiconductor layer 100a may be intrinsic or lightly doped. For example, the semiconductor layer 100a is lightly n-doped and contains phosphorus (P) and/or arsenic (As) atoms. A dopant concentration in the semiconductor layer 100a may be approximately uniform or may slightly increase or decrease with increasing distance to the process surface 101a. According to another embodiment, the dopant concentration in the semiconductor layer 100a may have a maximum value in a vertical distance to both the process surface 101a and a surface on the back, wherein the vertical direction is orthogonal to the process surface 101a.

On the process surface 101a a trench etch mask layer is formed that may include one single layer of a single material or two or more layers of different materials. For example, the trench etch mask layer may include at least a pad oxide layer, which may include a thermally grown semiconductor layer and/or deposited semiconductor oxide layers, e.g., thermal silicon oxide and/or deposited silicon oxide, as well as a silicon nitride layer. The trench etch mask layer may include further silicon oxide layers, a silicon oxynitride layer and/or a carbon layer.

From the trench etch mask layer, a photolithography process forms a trench etch mask 410 with mask openings 418 exposing first portions of the semiconductor layer 100a. By using the trench etch mask 410, trenches 160x are formed in the vertical projection of the mask openings 418, e.g., by reactive ion etching.

FIG. 2A shows the trench etch mask 410 on the process surface 101a of the semiconductor layer 100a. The mask openings 418 may have approximately equal widths along two orthogonal horizontal directions parallel to the process surface 101a. According to other embodiments, a first horizontal extension of the mask openings 418 is at least twice, e.g., at least ten times a second horizontal dimension orthogonal to the first horizontal dimension.

The trenches 160x extend from the process surface 101a into the semiconductor layer 100a. The trenches 160x may have approximately vertical sidewalls or may taper with increasing distance to the process surface 101a. The sidewalls of the trenches 160x may be slightly bowed. According to an embodiment, the sidewalls of the trenches 160x are vertical or taper with an angle of at most 20 from the vertical direction, wherein the sidewalls may be {100} crystal planes or slightly tilted to the {100} crystal planes. Mesas 170 of the semiconductor layer 100a separate neighboring trenches 160x.

An epitaxy mask 450 is formed that covers exposed top surfaces of the mesas 170. The epitaxy mask 450 may be a residual portion of the trench etch mask 410 of FIG. 2A or may be formed independently from the trench etch mask 410.

A mixture containing at least TCS and H₂ is supplied at a ratio of TCS:H₂ in a range from 1:20 to 1:4, e.g. from 1:15 to 1:5 a temperature of the semiconductor substrate 500a of 950° C., and at a barometric pressure of at least 50% standard atmosphere. TCS molecules or decomposition molecules of TCS decompose at the exposed surface of the semiconductor layer 100a, wherein silicon atoms arrange themselves in registry with the crystal lattice of the semiconductor layer 100a. At a mass flow of 4 slm TCS/H2 and a substrate temperature of at least 950° C. the trenches 160x are continuously filled, wherein during deposition of the crystalline silicon, intermediate surfaces 104 of the grown silicon in the trenches are V-like as indicated by the thin dotted lines in the leftmost trench 160x. The epitaxy mask 450 hampers crystal growth directly on the mesas 170.

The deposited crystalline silicon 165 may be intrinsic or approximately intrinsic with a net dopant concentration of at most 1E14 cm⁻³. Alternatively, the mixture may contain dopant gases such as B₂H₆, PH₃, AsH₃ in addition to TCS and H₂, wherein the silicon crystal may be grown with a net dopant concentration in a range from 1E15 cm⁻³ to 1E18 cm⁻³.

As shown in FIG. 2B the crystalline silicon 165 grown in the trenches 160x does not show shrinkage cavities or voids but forms an approximately perfect crystal, wherein a density of lattice defects is not or not significantly higher than in the mesas 170 separating neighboring trenches 160x. The deposited crystalline silicon 165 may fill the mask openings 418 of FIG. 2A and may laterally overgrow portions of the epitaxy mask 450 directly adjoining to the mask openings 418.

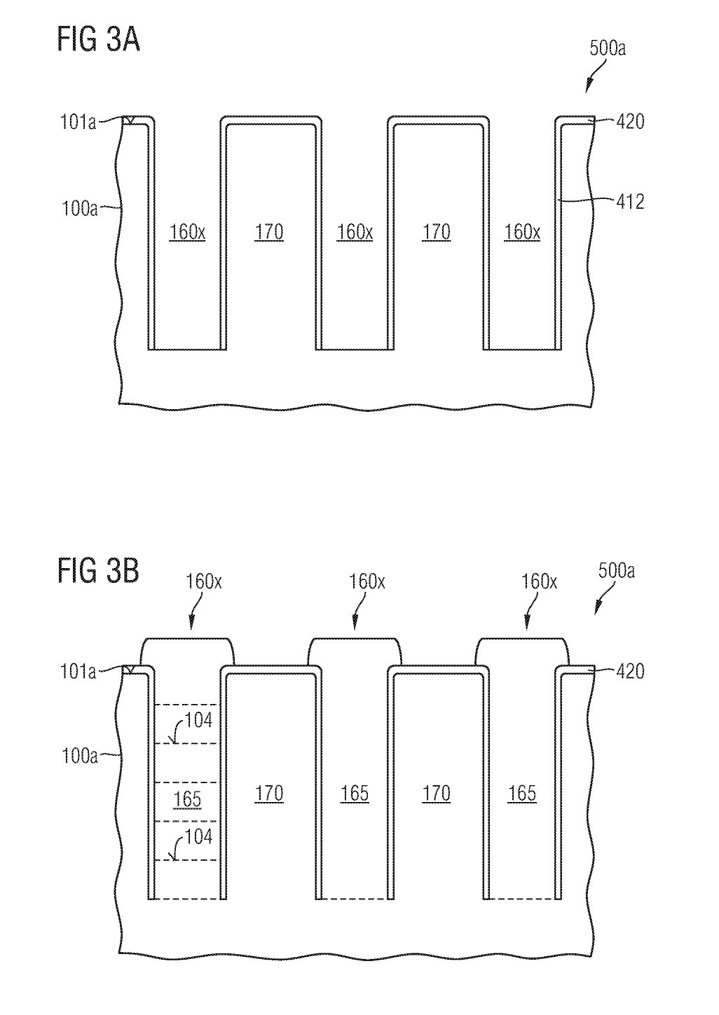

Other than in FIGS. 2A and 2B, the semiconductor substrate 500a of FIGS. 3A to 3B includes a passivation liner 420 which covers sidewalls of the trenches 160x and which may also cover top surfaces of the mesas 170 that separate neighboring trenches 160x. The passivation liner 420 exposes a bottom of the trenches 160x, wherein along the bottom a surface of the trench 160x is inclined with respect to the sidewalls. In the illustrated embodiment the bottom is orthogonal to the trench sidewalls and parallel to the top surfaces of the mesas 170. According to other embodiments, the bottom may include rounded or chamfered portions connected to the sidewalls.

The passivation liner 420 may be a dielectric layer, for example a silicon oxide, silicon nitride or carbon liner. According to an embodiment the passivation liner 420 is a thermal oxide of the semiconductor material of the semiconductor layer 100a, for example, thermally grown silicon oxide in case the semiconductor layer 100a is of silicon. A thickness of the passivation liner 420 may be in a range from 20 nm to 150 nm, for example in a range from 50 nm to 120 nm. The passivation liner 420 may replace the trench etch mask such that the passivation liner 420 covers both the top surfaces of the mesas 170 and the sidewalls of the trenches 160x, or may be formed in addition to residuals of the trench etch mask such that the passivation liner 420 covers only the sidewalls of the trenches 160x.

The semiconductor substrate 500a is placed in a process chamber with a barometric pressure of at least 50% standard atmosphere and heated to at least 800° C., for example at least 950° C. In first periods, a mixture containing TCS and H₂ but without etching agent or with only a small amount of etching agents is introduced into the process chamber such that crystalline silicon is epitaxially deposited. In second periods that alternate with the first periods, an etching mixture containing an etching agent such as hydrochloride acid HCl is fed into the process chamber. The etching mixture may contain a carrier gas, e.g., H₂ but is devoid of a silicon source. A ratio of the first periods to the second periods may be in a range from 10:1 to 10:5, e.g., 10:3 and a total cycle period in a range from 10 s to 20 s, by way of example. The etching agent removes seeds of silicon from the passivation liner 420 such that growth of silicon on the passivation liner 420 is almost completely suppressed. Instead, the grown silicon steadily grows from the bottom into direction of the process surface 101a as indicated by the dotted lines indicating intermediate surfaces 104 of deposited silicon in the leftmost trench 160x. In addition, portions of the grown silicon crystal above the process surface 101a show high crystal quality with a density of crystal lattice defects not higher than in the semiconductor layer 100a.

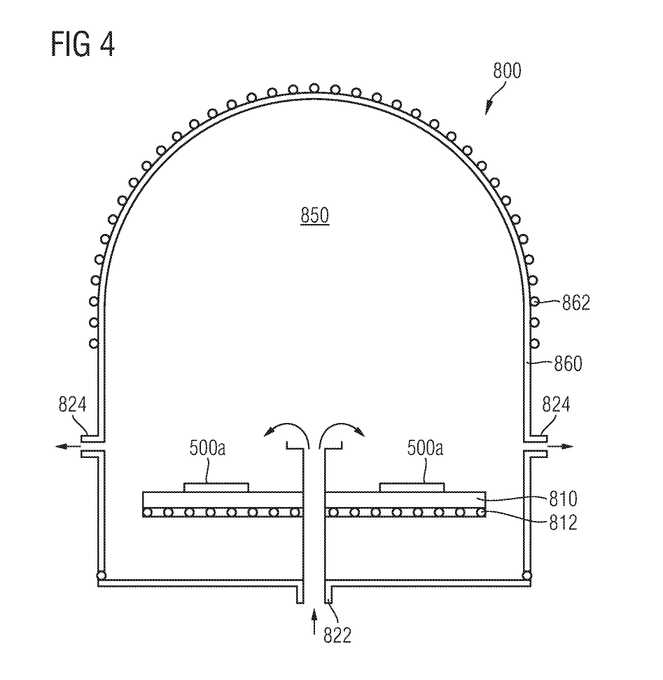

FIG. 4 is a schematic vertical cross-sectional view of a process reactor 800 for filling trenches in a semiconductor substrate 500a by epitaxial deposition of semiconductor material. In a process chamber 850, semiconductor substrates 500a such as silicon wafers lie on or are fixed at a support stage 810, which may include a stage heating member 812 for heating the semiconductor substrates 500a to a process temperature of at least 800° C., for example at least 950° C. An inlet 822 feeds a mixture of TCS and hydrogen at a defined mass flow into the process chamber 850. Through outlets 824 excess process gas and gaseous decomposition products leave the process chamber 850. A wall heating member 862 may heat the wall 860 of the process chamber 850 to a temperature of at least 400° C. The support stage 810 may be a circular disc or a plate oriented obliquely to a connection line between inlet 822 and outlet 824, which may be formed at opposite sides of the process chamber 850, or on lateral surfaces of a pyramidal support stage 810.

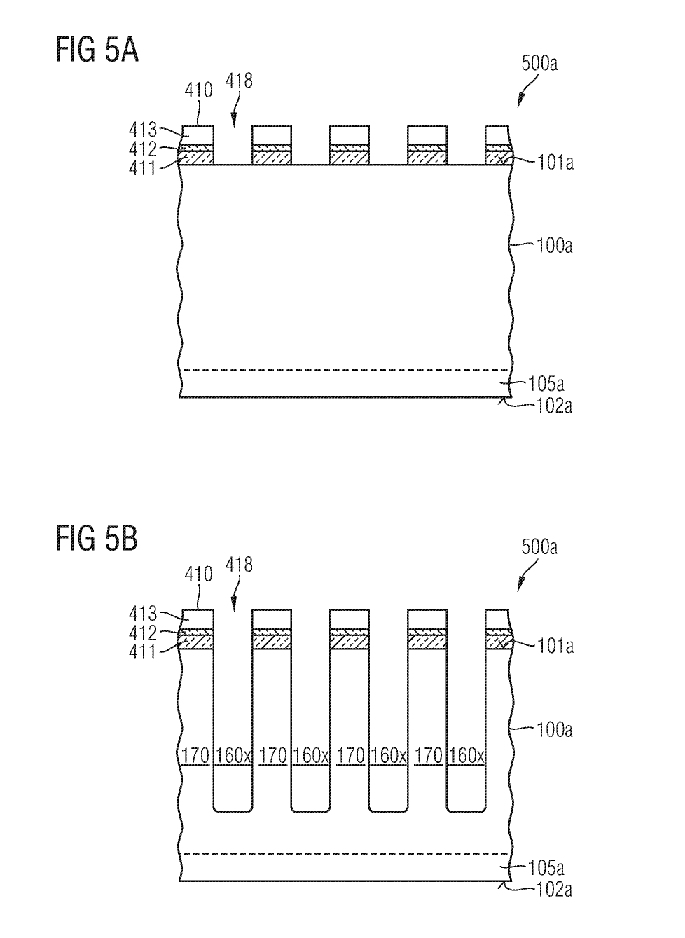

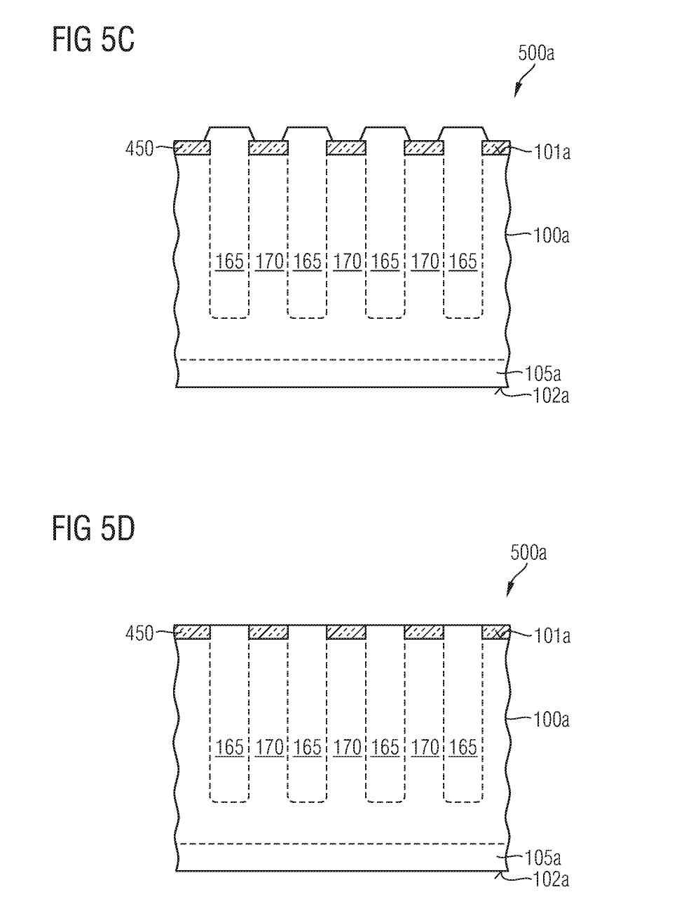

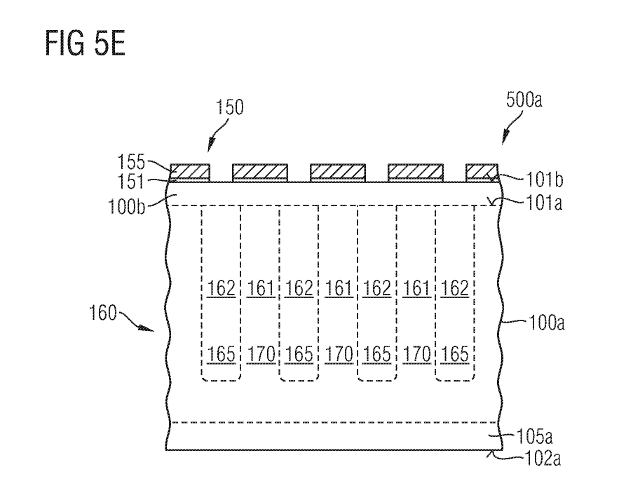

FIGS. 5A to 5E refer to further details of the formation of a superjunction structure by using TCS as silicon source.

FIG. 5A shows a trench etch mask 410 with mask openings 418. The trench etch mask 410 may include a first mask layer 411, which may be a silicon oxide layer. For example, the first mask layer 411 may contain or consist of thermally grown silicon oxide, deposited silicon oxide, for example silicon oxide deposited by LPCVD (low pressure chemical vapor deposition) using TEOS (tetraethylorthosilicate) as precursor material and densified in a heating treatment. A second mask layer 412 may be formed from a material with high etch selectivity against the material of the first mask layer 411. According to an embodiment, the second mask layer 412 contains or consists of silicon nitride. A third mask layer 413 may be a further silicon oxide layer or a silicate glass layer, for example, BSG (boron silicate glass), PSG (phosphorus silicate glass) or BPSG (boron phosphorus silicate glass), by way of example.

The mask openings 418 may form a regular pattern of stripes or dots, wherein a first width of the dots in the horizontal plane is at most ten times a second width of the dots orthogonal to the first width and wherein horizontal cross-sections of the dots may be circles, ellipses, ovals, distorted polygons or regular polygons such as octagons, hexagons or squares with or without rounded or chamfered corners.

A center-to-center distance between neighboring mask openings 418 may be in a range from 2 μm to 20 μm, for example in a range from 5 μm to 12 μm. A width of the mask openings 418 may be in a range from 500 nm to 10 μm, e.g., from 1 μm to 6 μm.

An etch process, e.g., reactive ion etching, uses the trench etch mask 410 to form trenches 160x in a vertical projection of the mask openings 418. Etching the trenches 160x may partially consume at least the third mask layer 413.

FIG. 5B shows the trenches 160x. Mesas 170 of the semiconductor layer 100a separate the trenches 160x from each other. A vertical extension of the trenches 160x may be in a range from 5 μm to 100 μm, for example in a range from 20 μm to 50 μm. An epitaxy mask may be formed, e.g., by remnants of the first mask layer 411.

The semiconductor substrate 500a is placed in a process chamber with a barometric pressure of at least 50%, e.g., at least 80% of standard atmosphere. In the process chamber the semiconductor substrate 500a is heated to a temperature of at least 800° C., for example, above 950° C. TCS and hydrogen gas are fed into the process chamber at a ratio of TCS:H₂ of about 1:5 and a total mass flow of 4 slm TCS/H2 and 0.8 slm HCl, wherein crystalline silicon 165 deposits in the trenches 160x. The process may stop when the deposited crystalline silicon 165 has laterally overgrown first portions of the epitaxy mask 450 covering the top surfaces of the mesas 170. The deposited crystalline silicon 165 takes the crystal orientation of the semiconductor layer 100a. The crystal defect density in the deposited crystalline silicon 165 does not exceed the crystal lattice density in the semiconductor layer 100a by more than 1000 ppm. Other than with deposition processes based on DCS at a barometric pressure below 50% standard atmosphere, the deposited crystalline silicon 165 above the process surface 101a and on the epitaxy mask 450 are single crystalline with a low density of crystal lattice defects, as shown in FIG. 5C.

Portions of the deposited crystalline silicon 165 outside of the trenches 160x of FIG. 5B are removed, for example by a CMP (chemical mechanical polishing) that may stop at the surface of the epitaxy mask 450.

FIG. 5D shows the planarized semiconductor substrate 500a with the deposited crystalline silicon 165 filling completely both the trenches 160x and mask openings of the epitaxy mask 450. Top surfaces of the deposited crystalline silicon 165 are flush with the exposed surface of the epitaxy mask 450, wherein the top surface of the deposited crystalline silicon 165 and the exposed surface of the epitaxy mask 450 forms a continuous plane.

The epitaxy mask 450 may be removed together with intermediate portions of the deposited crystalline silicon 165 in the openings of the epitaxy mask 450 such that after removal of the epitaxy mask 450 a resulting surface of the deposited crystalline silicon 165 is flush with the top surface of the mesas 170. For example, a plasma etch process may uniformly lower the planar surface irrespective of the different materials of the epitaxy mask 450 and the crystalline silicon 165. For example, the plasma process may etch an epitaxy mask 450 of silicon oxide and the deposited crystalline silicon 165 at the same rate.

An epitaxial layer 100b may be formed on the process surface 101a. A conformal gate dielectric layer may be formed, i.e. by thermal oxidation on the exposed epitaxy surface 101b. A conformal conductive gate layer, e.g., a doped polycrystalline silicon layer may be formed on the conformal gate dielectric layer. The conductive gate layer may be patterned by photolithography to form separated planar gate structures 150 with gate electrodes 155, which may be aligned to oppositely doped first and second regions 161, 162 of a superjunction structure 160 and which are separated from the semiconductor layer 100a by gate dielectrics 151. The superjunction structure 160 may result from the trench fill process of FIGS. 5A to 5C in different ways.

For example, the deposited crystalline silicon 165 of FIG. 5C is intrinsic or has only a low concentration of dopants, whereas the mesas 170 of the semiconductor layer 100a include donators and acceptors with different diffusion lengths. First regions 161 and second regions 162 of the superjunction structure 160 are formed by separating the dopants by a diffusing dopants with a larger diffusion length out of the mesas 170. The out-diffused dopant type with the larger diffusion length may form the first regions 161 in the deposited crystalline silicon 165. The dopant type with the shorter diffusion length may form the second regions 162 in the mesas 170.

According to the embodiment illustrated in FIG. 5E, the mesas 170 have a first conductivity type, for example, n-type and form the first regions 161 and the deposited crystalline silicon 165 is of the complementary conductivity type, for example, p-type and forms the second regions 162. The epitaxial layer 100b may have a thickness less than 5 μm, e.g., less than 3 μm.

According to a further embodiment, the mesas 170 may be intrinsic or only lightly doped. First portions of the deposited crystalline silicon 165 in first trenches are n-type and second portions of the deposited crystalline silicon 165 in second trenches between neighboring first trenches are p-type.

The dopant concentrations in the first and second regions 161, 162 as well as the dimensions of the first and second regions 161, 162 are selected such that the charge carriers in the superjunction structure 160 approximately compensate each other and the superjunction structure 160 fully depletes at voltages below the maximum blocking voltage of a semiconductor device obtained from the semiconductor substrate 500a.

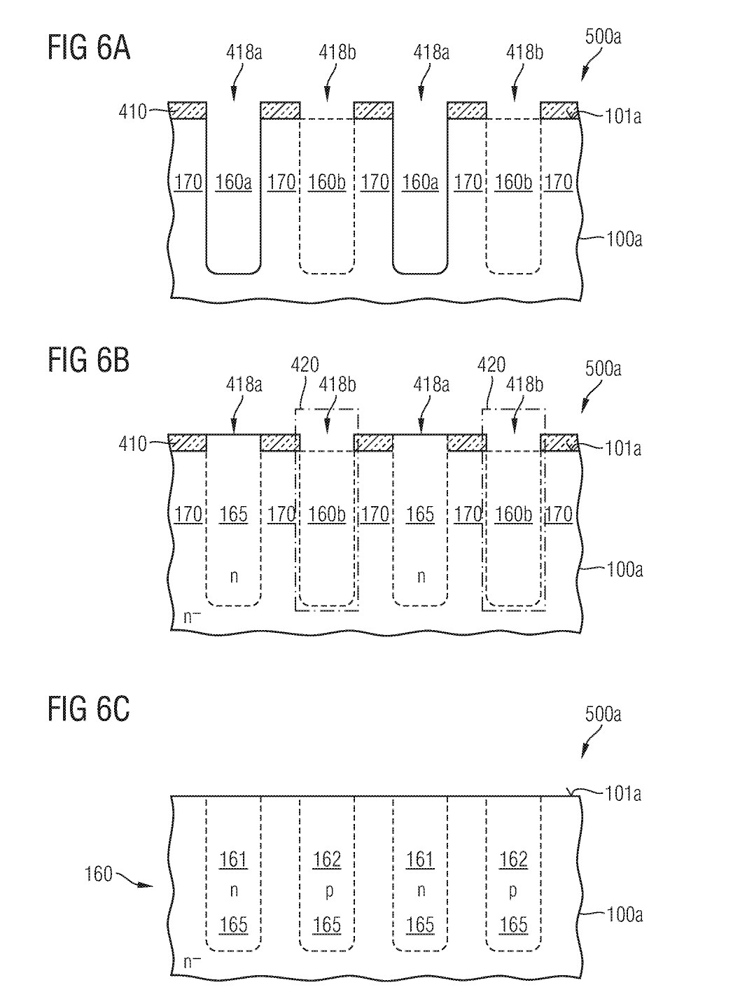

FIGS. 6A to 6C refer to the manufacture of a semiconductor device with both the n-doped regions and the p-doped regions formed in trenches. A trench etch mask layer as described above may be deposited on a process surface 101a of a semiconductor layer 100a.

From the trench etch mask layer, a photolithography process forms a trench etch mask 410 with first mask openings 418a exposing first portions of the semiconductor layer 100a and with second mask openings 418b exposing second portions of the semiconductor layer 100a. The first and second mask openings 418a, 418b alternate along one horizontal direction parallel to the process surface 101a or along two orthogonal horizontal directions parallel to the process surface 101a.

By using the trench etch mask 410, first trenches 160a are formed in the vertical projection of the first mask openings 418a and second trenches 160b may be formed in the vertical projection of the second mask openings 418b in the semiconductor layer 100a. The first and second trenches 160a, 160b may be formed contemporaneously or at different points in time. The trench etch may include reactive ion etching.

FIG. 6A shows the trench etch mask 410 on the process surface 101a of the semiconductor layer 100a, wherein first mask openings 418a and second mask openings 418b alternate along a first horizontal direction. The first and second mask openings 418a, 418b may have the same shape and the same dimensions. According to an embodiment, the first and second mask openings 418a, 418b have approximately equal widths along two orthogonal horizontal directions. According to other embodiments, a first horizontal extension of the first and second mask openings 418a, 418b is at least twice, e.g., at least ten times a second horizontal dimension orthogonal to the first horizontal dimension.

The first trenches 160a and, if applicable, the second trenches 160b extend from the process surface 101a into the semiconductor layer 100a. The second trenches 160b are not necessarily formed at this stage as indicated by the dotted lines. Vertical extensions of the first and second trenches 160a, 160b orthogonal to the process surface 101a may be equal. According to other embodiments, the first trenches 160a may have a greater vertical extension than the second trenches 160b.

The first and second trenches 160a, 160b may have approximately vertical sidewalls or may taper with increasing distance to the process surface 101a. According to a further embodiment, the sidewalls of the first and second trenches 160a, 160b may be slightly bowed.

First regions 161 of a first conductivity type are formed selectively in the first trenches 160a by using TCS as silicon source as described above, wherein a differentiator mask 430 hampers the formation of further first semiconductor regions in the second trenches 160b. The differentiator mask 430 may either effect that the second trenches 160b have not been formed at a point in time when the first regions 161 are formed or, if the second trenches 160b have already been formed at that point in time, prevents further first doped regions from being formed in the second trenches 160b.

The differentiator mask 430 may include a passivation liner mask that selectively lines the second trenches 160b, passivation plugs selectively filling the second trenches 160b, and/or a passivation layer mask that spans the second trenches 160b during formation of the first regions 161 or that fills or covers the second mask openings 418b during formation of the first trenches 160a.

FIG. 6B shows the first regions 161 formed exclusively in the first trenches 160a, while the second trenches 160b are either not formed at this point in time or protected against the formation of first regions 161 by the differentiator mask 430. The first regions 161 may consist of or contain first portions of crystalline silicon 165 grown by epitaxy on surface portions of the semiconductor layer 100a exposed in the first trenches 160a.

Then the second trenches 160b are either formed or exposed by removing the differentiator mask 430 and second regions 162 of a second conductivity type opposite to the first conductivity type are formed in the second trenches 160b by using TCS as silicon source as described above. Apart from the dopants and the conductivity type, the material of the second regions 162 may be the same as the material of the first regions 161.

The first and second regions 161, 162 shown in FIG. 6C form a superjunction structure 160 and are formed by selective epitaxy of in-situ doped semiconductor material, wherein the epitaxy uses TCS and H₂ as source gases at a barometric pressure of at least 50% of standard atmosphere and a temperature of at least 900° C.

Since both the first and the second regions 161, 162 are formed by filling trenches, the degree of compensation can be finely and reliably adjusted. Since both the first and the second regions 161, 162 are defined by the same trench etch mask, variations of the horizontal cross-sectional areas among the first and second regions 161, 162 are drastically reduced compared to other trench approaches. Conformity of the degree of compensation is subjected to lower fluctuations both within the same device, among devices obtained from the same semiconductor substrate 500a and among devices obtained from different semiconductor substrates 500a.

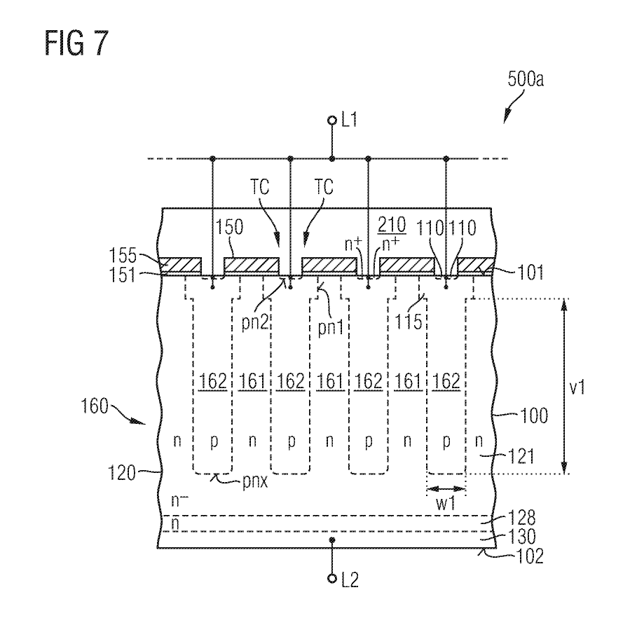

FIG. 7 shows a semiconductor device 500a, which may be or may include an IGFET, an IGBT, or a power semiconductor diode. The semiconductor device 500a includes functional transistor cells TC or an anode zone of a power semiconductor diode through which a load current directly flows in an on-state or forward mode of the semiconductor device 500a.

The semiconductor device 500a may include a semiconductor portion 100 of a semiconductor material with cubic crystal lattice such as crystalline silicon. The semiconductor portion 100 may include a drift structure 120 with a superjunction structure 160 including first and second regions 161, 162 as described with reference to FIG. 6C and may include further conductive, dielectric or semiconducting portions.

The transistor cells TC may be formed along a first surface 101 of the semiconductor portion 100. The transistor cells TC may be based on trench gates or planar gates with gate structures 150 as described with reference to FIG. 5E.

The transistor cells TC include body zones 115 forming first pn junctions pn1 with the first regions 161 of the superjunction structure 160 and second pn junctions pn2 with source zones 110. The body zones 115 may be wells extending from the first surface 101 into the semiconductor portion 100. The source zones 110 may be wells extending from the first surface 101 into the body zones 115. The source zones 110 and the body zones 115 may be electrically connected to a first load terminal L1. The gate dielectric 151 capacitively couples the gate electrode 155 to channel portions of the body zones 115.

Along a second surface 102 opposite to the first surface 101 the semiconductor portion 100 may include a heavily doped contact layer 130 electrically connected to a second load terminal L2. A field stop layer 128 with a lower dopant concentration as the contact layer 130 may be sandwiched between the contact layer 130 and a low doped drift zone 121.

An aspect ratio of a vertical extension vi of the second regions 162 to a horizontal width w1 of the second regions 162 is at least 20.

Although specific embodiments have been illustrated and described herein, it will be appreciated by those of ordinary skill in the art that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method of manufacturing a semiconductor device, the method comprising:
forming trenches in a semiconductor layer of a semiconductor substrate; and
feeding a mixture containing trichlorosilane and hydrogen gas into a process chamber containing the semiconductor substrate, wherein a barometric pressure in the process chamber is at least 50% of standard atmosphere and wherein the trenches are filled with epitaxially deposited crystalline silicon.

2. The method of claim 1, wherein the semiconductor layer has a cubic crystal lattice and sidewalls of the trenches are (100) crystal planes.

3. The method of claim 1, wherein the mixture containing trichlorosilane and hydrogen gas is continuously supplied to the process chamber at least until the trenches are filled with the epitaxially deposited crystalline silicon.

4. The method of claim 1, wherein the mixture contains hydrochloride acid and is continuously supplied to the process chamber until the trenches are filled with the epitaxially deposited crystalline silicon.

5. The method of claim 1, wherein an epitaxy mask covers top surfaces of mesas of the semiconductor layer during deposition of the crystalline silicon by epitaxy, the mesas separating neighboring ones of the trenches, respectively, and the epitaxially deposited crystalline silicon laterally overgrowing first portions of the epitaxy mask directly adjoining to the trenches.

6. The method of claim 1, further comprising:
forming, before depositing the crystalline silicon by epitaxy, a passivation liner in the trenches, the passivation liner covering sidewalls of the trenches and exposing bottoms of the trenches.

7. The method of claim 6, wherein the mixture containing trichlorosilane is supplied to the process chamber in first periods separated by second periods at least until the trenches are filled with the epitaxially deposited crystalline silicon.

8. The method of claim 7, wherein an etching mixture containing an etching agent is supplied to the process chamber in the second periods.

9. The method of claim 8, wherein the etching mixture contains hydrochloride acid such that trichlorosilane and hydrochloride acid are alternatingly fed into the process chamber.

10. The method of claim 6, wherein an epitaxy mask covers top surfaces of mesas of the semiconductor layer during deposition of the crystalline silicon by epitaxy, the mesas separating neighboring ones of the trenches, respectively, and the epitaxially deposited crystalline silicon laterally overgrowing first portions of the epitaxy mask directly adjoining the trenches.

11. The method of claim 1, wherein the epitaxially deposited crystalline silicon contains donors, acceptors, or both donors and acceptors.

12. The method of claim 1, wherein a first portion of the epitaxially deposited crystalline silicon deposited in first trenches contains donors and a second portion of the epitaxially deposited crystalline silicon deposited in second trenches contains acceptors.

13. The method of claim 1, wherein a temperature of the semiconductor substrate is at least 920° Celsius during deposition of the crystalline silicon.

14. The method of claim 1, wherein a total mass flow of trichlorosilane and hydrogen gas into the process chamber is in a range from 2 slm to 6 slm.

15. The method of claim 1, wherein the barometric pressure in the process chamber is at least 90% of standard atmosphere.

16. The method of claim 1, wherein the deposited crystalline silicon forms at least first regions of a superjunction structure.

17. A super junction semiconductor device, comprising:
a semiconductor portion that comprises a drift structure comprising n-doped first regions and p-doped second regions,
wherein the first and second regions alternate along at least one horizontal direction parallel to a first surface of the semiconductor portion,
wherein an aspect ratio of a vertical extension of the second regions to a horizontal width of the second regions is at least 20.

18. The super junction semiconductor device of claim 17, wherein surfaces that connect points of equal dopant concentration in the first and second regions are not undulated.

19. The super junction semiconductor device claim 17, wherein at half a distance between vertical center axes of directly adjoining first and second regions a concentration of donors is at most 30% of a maximum dopant concentration in the first regions.
